(19) United States
(12) Patent Application Publication
(10) Pub. No.: US 2008/0142964 A1
(43) Pub. Date: Jun. 19, 2008

(54) Tubular-shaped bumps for integrated circuit devices and methods of fabrication

(76) Inventors: Haixiao Sun, Pudong (CN); Daoqiang Lu, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/638,145

(22) Filed: Dec. 13, 2006

(51) Int. Cl. H01L 23/48; H01L 21/441

(52) U.S. Cl. 257/737; 438/613; 257/E23.021; 257/E21.477

(57) ABSTRACT

An integrated circuit die includes one or more tubular-shaped conductive bumps disposed on one side thereof. The tubular-shaped bumps may comprise copper, and may be used for input/output (I/O) signaling. The die may also include solid bumps for I/O and/or power delivery. The tubular-shaped bumps are relatively more compliant than the solid bumps, and may alleviate the effects of thermally induced stresses. Other embodiments are described and may be claimed.

### FIELD OF THE INVENTION

The disclosed embodiments relate generally to the manufacture of integrated circuit devices, and more particularly to tubular-shaped bumps that may be used to create compliant interconnects between an integrated circuit die and a substrate.

### BACKGROUND OF THE INVENTION

An integrated circuit (IC) device typically comprises a semiconductor die in which circuitry has been formed, this circuitry including a collection of circuit elements such as transistors, diodes, capacitors, resistors, etc. To provide electrical connections between the die and a next-level component (e.g., a package substrate), an interconnect structure is formed over a surface of the die. The interconnect structure may comprise a number of levels of metallization, each layer of metallization separated from adjacent levels by a layer of dielectric material and interconnected with the adjacent levels by vias. The dielectric layers of the interconnect structure are often each referred to as an “interlayer dielectric” (or “ILD”). The metallization on each layer comprises a number of conductors (e.g., traces) that may route signal, power, and ground lines to and from the circuitry formed on the die.

Disposed in an uppermost layer of the interconnect structure are a number of bond pads. Typically, a portion of these bond pads will be used for transmitting input/output (I/O) signals to and from the IC die, whereas another portion of these pads will be used for delivering power to the die. An electrically conductive bump may be disposed on each of these bond pads, and these conductive bumps can be used to form electrical connections with, for example, a package substrate, which may include a mating array of pads. By way of example, copper bumps may be formed on the IC die bond pads, and a quantity of solder (e.g., a solder layer or a solder bump) may be disposed on each of the substrate pads. The copper bumps on the IC die are aligned with the array of pads on the substrate, and a solder reflow process is performed to electrically (and mechanically) couple the copper bumps to the substrate, thereby forming a number of interconnects between the die and substrate.

Due to differences in the coefficients of thermal expansion (CTE) between the IC die, which may comprise silicon, and the substrate (as well as the materials used to form the interconnect structure on the die), thermally induced stresses may occur during and after (e.g., during cooling) the reflow process. These thermally induced stresses can lead to cracking and other failures (e.g., delamination) in the interconnect structure of the IC die, and perhaps also to stress-induced damage to the interconnects themselves. The impact of these stresses may be most pronounced near the periphery and corners of the IC die, where the greatest amount of thermal expansion of the die will occur. The above-described effects brought on by thermally induced stresses and the resulting potential for failures may be most pronounced where lead-free solders (which have a relatively higher reflow temperature) are used to form the interconnects and, in addition, where low-k dielectric materials (which are relatively weaker) are used in the interconnect structure on the die.

### BRIEF DESCRIPTION OF THE DRAWINGS

FIG. 1A is a schematic diagram illustrating an embodiment of an integrated circuit (IC) die having one or more tubular-shaped conductive bumps.

FIG. 1B is a schematic diagram illustrating a partial cross-sectional view of IC die of FIG. 1A, as taken along line B-B of FIG. 1A.

FIG. 1C is a schematic diagram illustrating another embodiment of a tubular-shaped conductive bump.

FIG. 1D is a schematic diagram illustrating a further embodiment of a tubular-shaped conductive bump.

FIG. 1E is a schematic diagram illustrating another embodiment of an IC die having one or more tubular-shaped conductive bumps.

FIG. 2 is a schematic diagram showing the IC die of FIG. 1A disposed on a package substrate.

FIG. 3 is a block diagram illustrating an embodiment of a method for forming a tubular-shaped conductive bump.

FIGS. 4A-4G are schematic diagrams illustrating embodiments of the method shown in FIG. 3.

### DETAILED DESCRIPTION OF THE INVENTION

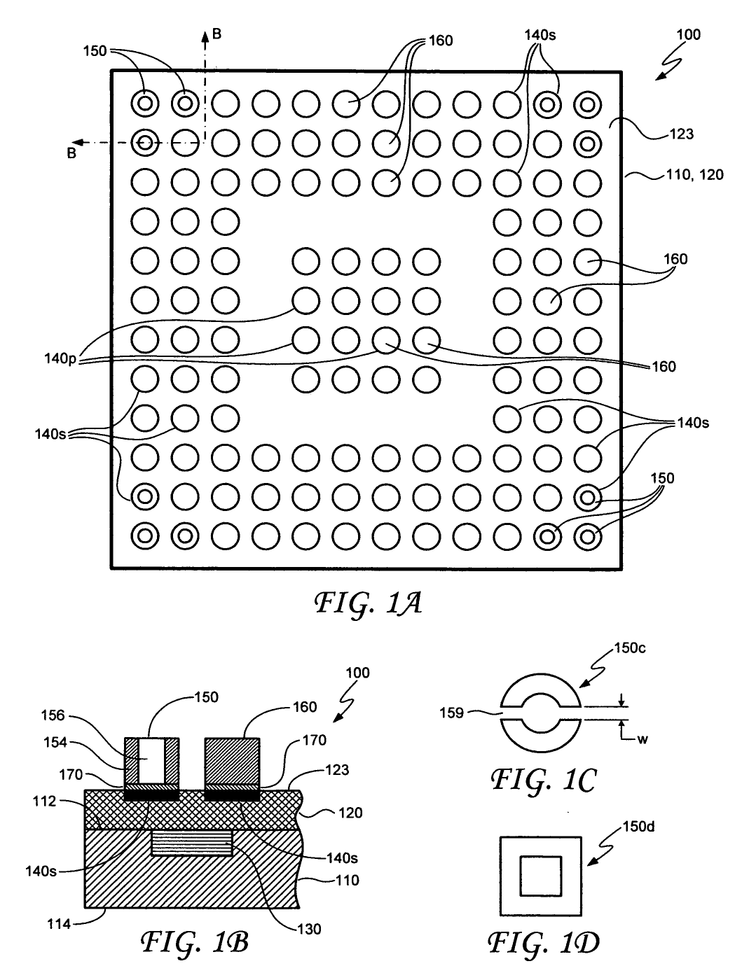

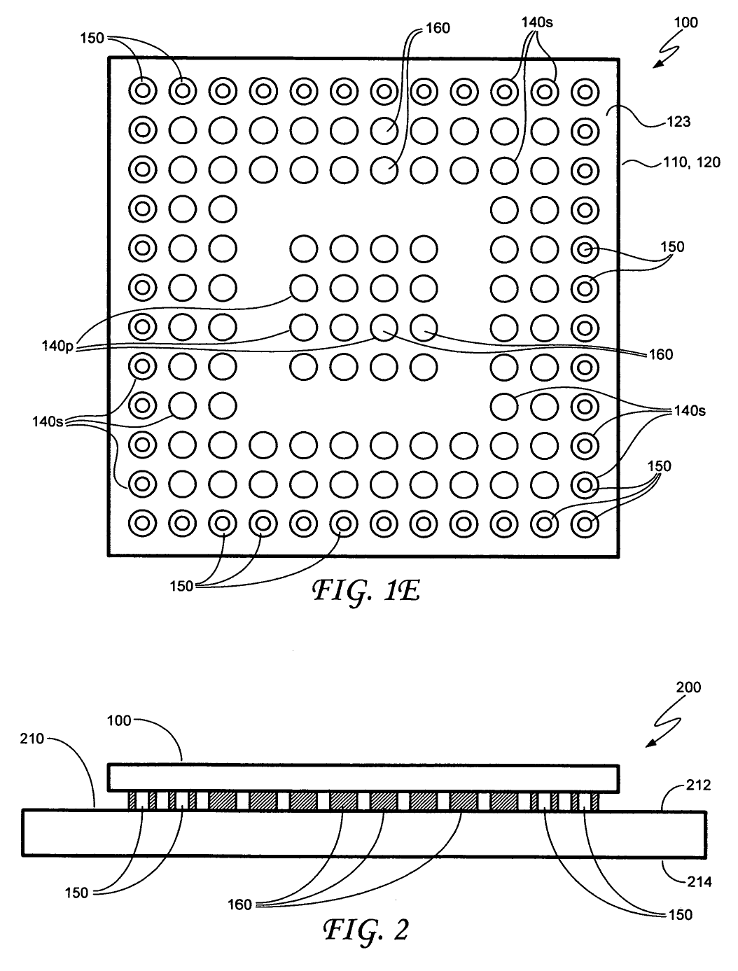

Referring to FIGS. 1A and 1B, illustrated is an embodiment of an integrated circuit (IC) die 100. The IC die includes a substrate 110 having a front side 112 and an opposing back side 114. Substrate 110 may comprise any suitable semiconductor material, and in one embodiment the substrate 110 comprises silicon. However, the disclosed embodiments are not limited to silicon, and the substrate 110 may comprise any other material or combination of materials (e.g., gallium arsenide, silicon-on-insulator, or SOI, etc.). One or more integrated circuits is formed on the front side 112 of substrate 110, and this circuit (or circuits) comprises a collection of circuit elements 130 (only one element shown in FIG. 1B for ease of illustration), such as transistors, diodes, capacitors, resistors, etc.

To provide electrical connections between the IC die 100 and a next-level component (e.g., a package substrate or other die carrier), an interconnect structure 120 is disposed over the front side 112 of substrate 110. The interconnect structure may comprise a number of levels of metallization, each layer of metallization separated from adjacent levels by a layer of dielectric material and interconnected with the adjacent levels by vias. The dielectric layers of the interconnect structure are often each referred to as an “interlayer dielectric” (or “ILD”). The ILD material may comprise any suitable dielectric material, such as carbon-doped oxide (CDO), silicon dioxide, SiOF, a glass, or a polymer material. In one embodiment, the ILD material comprises a “low-k” dielectric material. In another embodiment, the dielectric material may be porous and/or the interconnect structure 120 may include air gaps to lower the effective dielectric constant of the ILD layers. The metallization on each layer comprises a number of conductors (e.g., traces) that may route signal, power, and ground lines to and from the circuitry formed on the die. These conductors may comprise any suitable conductive material, and in one embodiment the metallization layers comprise copper or a copper alloy. However, the disclosed embodiments are not limited to copper, and the metallization within the interconnect structure 120 may comprise any other suitable material (e.g., gold, silver, aluminum, as well as alloys of these and/or other metals).

Disposed on an upper surface 123 of the interconnect structure 120 are a number of bond pads 140. A portion of the bond pads 140s are for transmitting input/output (I/O) signals to and from the die 100, whereas another portion of the bond pads 140p are for delivering power (and ground) to the die. The bond pads 140 may have any suitable arrangement. In one embodiment, as shown in FIGS. 1A (and 1E), the die 100 includes an inner array of bond pads 140p (e.g., for power and ground) located proximate the center of the die, and an outer array of bond pads 140s (e.g., for I/O signals) located toward the die's periphery, with a gap or spacing (having no bond pads) separating the inner and outer arrays. However, it should be understood that die 100 may have any other suitable arrangement of bond pads (e.g., there may be no gap separating the inner array of power and ground pads 140p from the outer array of I/O signal pads 140s, I/O signal pads may be present proximate the center of the die and/or power and ground pads may be present proximate the outer perimeter of the die, etc.).

According to one embodiment, the bond pads 140s, 140p may comprise copper or a copper alloy. However, it should be understood that the bond pads may comprise any other suitable conductive material, such as gold, silver, aluminum, nickel, as well as alloys of these and other metals. Also, it should be understood that a bond pad 140 may, in one embodiment, comprise a stack-up of multiple, discrete layers of metal.

Disposed on one or more of the bond pads is a tubular-shaped bump (or column) 150, and disposed one or more of the other bond pads is a solid bump (or column) 160. Each tubular-shaped bump 150 comprises an annular wall 154 surrounding a hollow center 156 (see FIG. 1B). For high frequency electrical signals, the current exists primarily in a region proximate the outer diameter of a conductor, and the current level falls off exponentially with depth below the outer surface. Thus, in high frequency signaling, the signals will travel primarily in a thin shell proximate the outer surface of a conductor and, therefore, the use of tubular-shaped bumps 150 should have minimal impact on I/O signals. However, the tubular-shaped bumps 150 are more compliant than their solid counterparts 160. Accordingly, use of the tubular-shaped bumps 150 can lower the stresses (e.g., thermally induced stresses resulting from CTE mismatches) present in the interconnect structure 120.

The tubular-shaped bumps 150 and solid bumps 160 may comprise any suitable conductive material, and in one embodiment these bumps comprise copper or a copper alloy. However, the disclosed embodiments are not limited to the use of copper, and other conductive materials may be utilized to form the bumps 150, 160 (e.g., solder materials, conductive polymers, etc.). Also, the tubular-shaped bumps 150 may have any suitable dimensions. According to one embodiment, each tubular-shaped bump 150 (and perhaps each solid bump 160) has an outer diameter in a range between approximately 50 μm and 200 μm. In another embodiment, the annular wall 154 of each tubular-shaped bump 150 has a thickness in a range between approximately 10 μm and 50 μm. In a further embodiment, each tubular-shaped bump 150 (and perhaps each solid bump 160) has a height in a range between approximately 50 μm and 300 μm.

In one embodiment, a seed layer 170 is disposed over each bond pad 140 and under the corresponding bump 150, 160 (see FIG. 1B). The seed layer 170 may be used in the formation of the bumps 150, 160 by an electroplating process, and this seed layer may comprise any suitable material. For example, where the bumps 150, 160 comprise copper, the seed layer 170 may comprise titanium.

According to one embodiment, as shown in FIGS. 1A and 1B, the annular wall 154 has a generally circular shape that is continuous (e.g., no gaps) about it's circumference. However, the disclosed embodiments are not limited to such a circular-shaped bump. For example, as shown in FIG. 1C, a tubular-shaped bump 150c may have one or more gaps 159 distributed about it's circumference. The gaps 159 may facilitate the evaporation of flux and/or the flow of deflux solution into the center hollow region 156. In one embodiment, the gaps 159 have a width (w) in a range between approximately 20 μm and 100 μm. By way of further example, a tubular-shaped bump may have a non-circular configuration, such as the generally square-shaped hollow bump 150d shown in FIG. 1D (the solid bumps 160 perhaps having a similar shape in this embodiment). As the reader will appreciate, the tubular-shaped bumps 150 may have any other suitable shape or configuration (e.g., oval, hexagonal, triangular, etc.).

The die 100 may include any suitable number of tubular-shaped bumps 150 positioned at any suitable locations on the die. For example, as shown in FIG. 1A, a small number of I/O bumps (e.g., three) located proximate each corner of the die 100 may comprise the tubular-shaped bumps 150. By way of further example, as shown in FIG. 1 E, all of the I/O bumps located nearest the die's periphery may comprise tubular-shaped bumps 150. However, it should be understood that many other configurations are possible (e.g., all I/O bumps may comprise tubular-shaped bumps, only a single bump at each die corner may comprise a tubular-shaped bump, etc.). Also, in the illustrated embodiments, the tubular-shaped bumps 150 are disposed on I/O bond pads 140s. However, in other embodiments, a tubular-shaped bump 150 may be disposed on a power or ground pad 140p (e.g., for low power applications).

Referring to FIG. 2, illustrated is an embodiment of an assembly 200 including the die 100 of FIGS. 1A-1B. Assembly 200 includes a package substrate (or other die carrier 210) upon which the die 100 has been disposed. It should be noted that the IC die 100 may comprise any desired type of integrated circuit device. In one embodiment, the IC die 100 comprises a processing device, such as a microprocessor, a graphics processor, an application specific integrated circuit (ASIC), a field programmable gate array (FPGA), etc. In another embodiment, the IC die 100 comprises a memory device, such as any type of dynamic random access memory (DRAM), a flash memory, etc. It should be understood that these are but a few examples of the types of IC devices which die 100 may comprise and, further, that the die 100 may comprise any other type of IC device (e.g., a wireless communications device, a chip set, a MEMS device, a memory controller, etc.).

With continued reference to FIG. 2, the substrate 210 may comprise any suitable type of package substrate or other die carrier. In one embodiment, the substrate 210 comprises a multilayer substrate including a number of alternating layers of metallization and dielectric material. Each layer of metallization comprises a number of conductors (e.g., traces), and these conductors may comprise any suitable conductive material, such as copper. Further, each metal layer is separated from adjacent metal layers by the dielectric layers, and adjacent metal layers may be electrically interconnected by conductive vias. The dielectric layers may comprise any suitable insulating material—e.g., polymers, including both thermoplastic and thermosetting resins or epoxies, ceramics, etc.—and the alternating layers of metal and dielectric material may be built-up over a core layer of a dielectric material (or perhaps a metallic core).

The substrate 210 includes a first side 212 and an opposing second side 214. A number of pads (not shown in figures) or other electrically conductive terminals are disposed on the substrate's first side 212, and these pads are arranged to couple with the bumps 150, 160 extending from die 100. A layer of solder (e.g., solder bumps) may be disposed on each of the substrate pads, and these pads (or other terminals) are electrically coupled—e.g., as by a reflow process—with the die bumps 150, 160 to form electrically conductive interconnects between the substrate 210 and the die 100. In addition, a number of electrically conductive terminals (not shown in figures), such as metal pads, metal bumps, columns, pins, etc., may also be disposed on the substrate's second side 214, and these terminals may be used to electrically couple the assembly 200 with a next-level component (e.g., a printed circuit board, etc.).

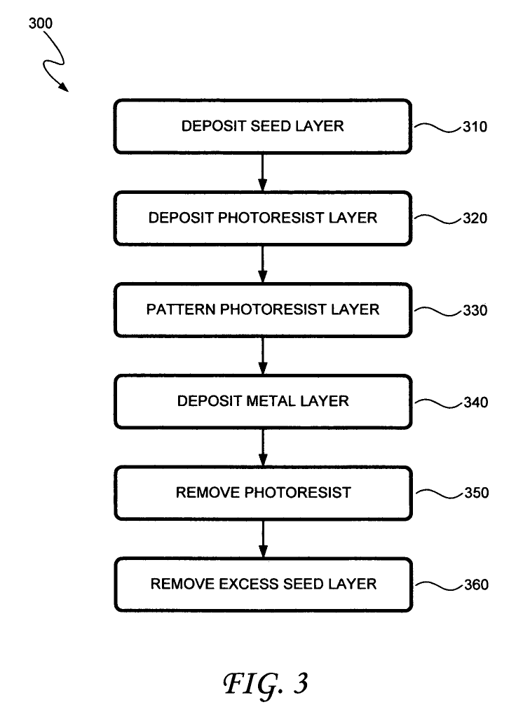

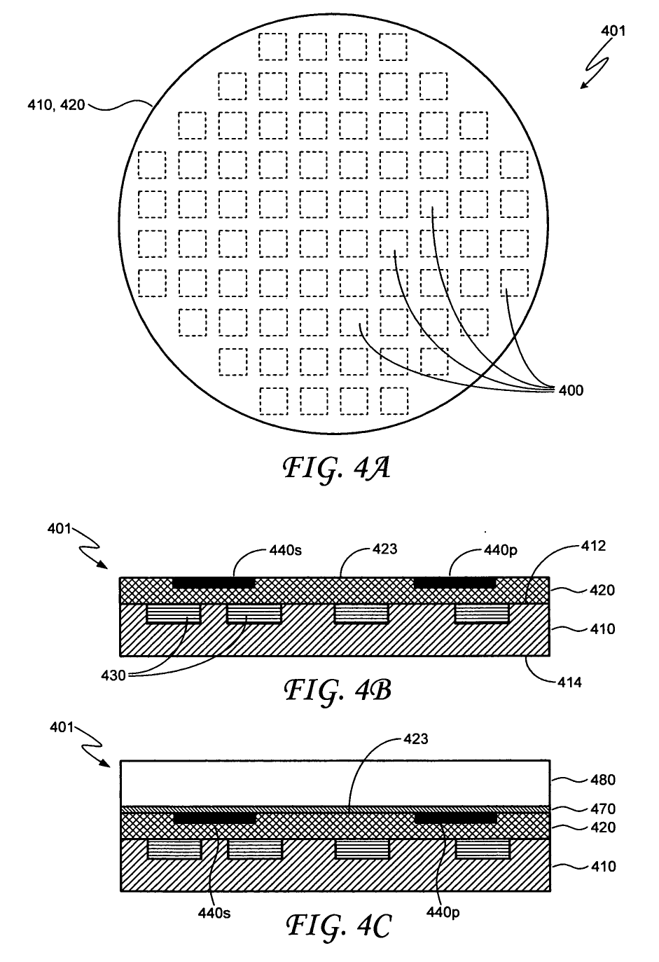

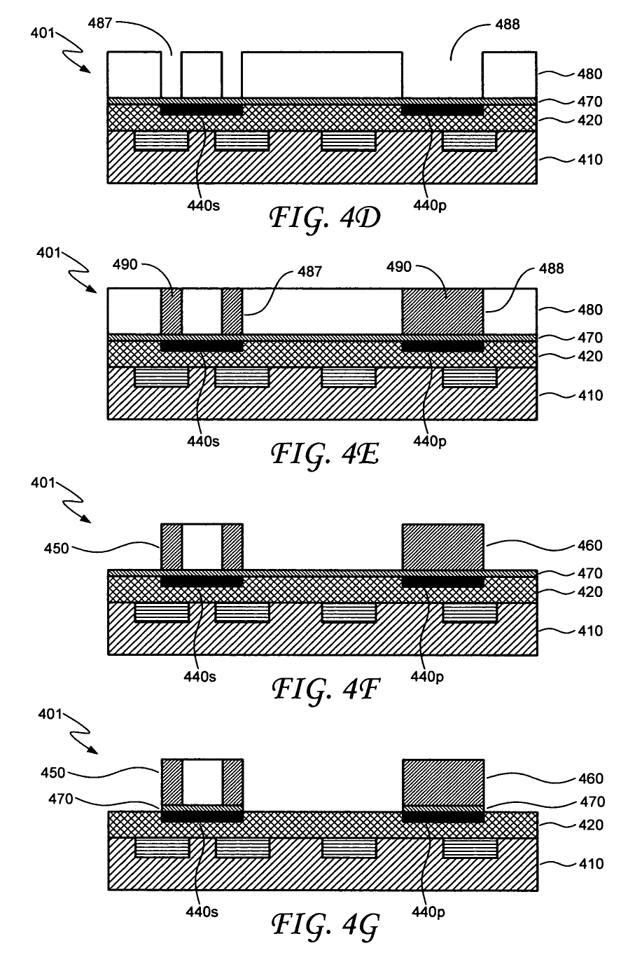

Turning now to FIG. 3, illustrated is an embodiment of a method 300 for forming a tubular-shaped conductive bump (e.g., the tubular-shaped bumps 150, 150c, or 150d). The method 300 of FIG. 3 is further illustrated in the schematic diagrams of FIGS. 4A through 4G, and reference should be made to these drawings as called out in the text below.

Referring first to FIGS. 4A and 4B, illustrated is an embodiment of a semiconductor wafer 401 upon which integrated circuitry for a number of die 400 has been formed. The wafer includes a substrate 410 having a front side 412 and an opposing back side 414. The substrate 410 may comprise any suitable semiconductor material, and in one embodiment the substrate 410 comprises silicon. However, the disclosed embodiments are not limited to silicon, and the substrate 410 may comprise any other material or combination of materials (e.g., gallium arsenide, SOI, etc.). As noted above, one or more integrated circuits have been formed on the front side 412 of substrate 410, and these circuits comprises a collection of circuit elements 430, such as transistors, diodes, capacitors, resistors, etc.

To provide electrical connections between each IC die 400 and a next-level component (e.g., a package substrate or other die carrier), an interconnect structure 420 is disposed over the front side 412 of substrate 410. The interconnect structure may comprise a number of levels of metallization, each layer of metallization separated from adjacent levels by a layer of dielectric material (or “ILD layer”) and interconnected with the adjacent levels by vias. The ILD material may comprise any suitable dielectric material, such as CDO, silicon dioxide, SiOF, a glass, or a polymer material. In one embodiment, the ILD material comprises a “low-k” dielectric material. The metallization on each layer comprises a number of conductors (e.g., traces) that may route signal, power, and ground lines to and from the circuitry formed on each die. These conductors may comprise any suitable conductive material, and in one embodiment the metallization layers comprise copper or a copper alloy. However, the disclosed embodiments are not limited to copper, and the metallization within the interconnect structure 420 may comprise any other suitable material (e.g., gold, silver, aluminum, as well as alloys of these and/or other metals).

Disposed on an upper surface 423 of the interconnect structure 420 are a number of bond pads 440, wherein a portion of the bond pads are associated with each of the die 400. A portion of the bond pads 440s are for transmitting I/O signals to and from a die 400, whereas another portion of the bond pads 440p are for delivering power (and ground) to the die. The bond pads 440 on each die 400 may have any suitable arrangement (see discussion above). According to one embodiment, the bond pads 440s, 440p comprise copper or a copper alloy. However, it should be understood that the bond pads 440 may comprise any other suitable conductive material, such as gold, silver, aluminum, nickel, as well as alloys of these and other metals. Also, it should be understood that a bond pad 440 may, in one embodiment, comprise a stack-up of multiple, discrete layers of metal.

At this juncture, it should be noted that in FIG. 4B (and FIGS. 4C-4G) only one bond pad 440s and only one bond pad 440p are shown for ease of illustration. Further, a limited number of circuit elements 430 are shown in these figures, also for ease of illustration. However, it should be understood that, in practice, such a wafer 401 may include circuitry for several hundred die 400 and that each die may include hundreds of bond pads 440. Further, each die 400 may, in practice, include tens of millions or even hundreds of millions of individual circuit elements, as well as conductors interconnecting these circuit elements.

With reference now to block 310 in FIG. 3, according to one embodiment, a seed layer is formed on the wafer. This is illustrated in FIG. 4C, where a seed layer 470 has been deposited over the upper surface 423 of the interconnect structure 420, as well as over the bond pads 440s, 440p. As will be discussed below, conductive bumps will be disposed on the bond pads 440s, 440p. In one embodiment, these bumps will be formed by an electroplating process, and the seed layer 470 may comprise any material upon which the bumps may be deposited by such a plating process. For example, where the conductive bumps comprise copper, the seed layer may comprise titanium. Other seed layer materials will be suitable, depending upon the bump material and the application. The seed layer 470 may have any suitable thickness, and in one embodiment the seed layer has a thickness in a range between approximately 0.03 μm and 0.10 μm. Any suitable blanket deposition process may be employed to form the seed layer, such as a physical vapor deposition (PVD) process or a chemical vapor deposition (CVD) process.

As set forth in block 320, a layer of a photoresist (PR) material is formed over the wafer. This is also illustrated in FIG. 4C, where a PR layer 480 has been deposited over the seed layer 470. The PR layer 480 may comprise any suitable photoresist material capable of being patterned by lithography techniques, and this layer may be deposited by any suitable blanket deposition process (e.g., PVD, CVD, spin-coating, lamination, etc.). In one embodiment, the PR layer 480 has a thickness in a range between approximately 50 μm and 300 μm.

As set forth in block 330, the PR layer is patterned for the subsequent formation of conductive bumps. This is illustrated in FIG. 4D, where the PR layer 480 has been patterned to form annular opening 487 and opening 488. The annular opening 487 is disposed over the I/O bond pad 440s, whereas the opening 488 is disposed over the power bond pad 440p. Any suitable lithography techniques may be utilized to form the openings 487, 488.

As set forth in block 340, a metal layer is deposited over the seed layer. This is illustrated in FIG. 4E, where a metal layer 490 has been deposited over the seed layer 470 within each of the openings 487 and 488. Metal layer 490 may comprise any suitable conductive material, and in one embodiment this layer comprises copper or a copper alloy. However, other metals (e.g., a solder material) as well as non-metals (e.g., conductive polymers) may be used with the disclosed embodiments. According to one embodiment, the metal layer 490 is deposited using an electroplating process, wherein the metal layer 490 is formed on the exposed seed layer 470 in openings 487, 488. However, other deposition techniques may be employed (e.g., PVD, CVD, electroless plating, etc.), and a planarization process (e.g., chemical-mechanical polishing) may be performed to remove excess metal, if necessary.

As set forth in block 350, the PR layer is removed. This is illustrated in FIG. 4F, wherein the PR layer 480 has been removed. The metal layer disposed in the annular opening 487 forms a tubular-shaped bump 450 over signal pad 440s, and the metal layer disposed in the other opening 488 forms a solid bump 460 over power pad 440p. Any suitable stripping solution and/or technique may be used to remove the PR material.

As set forth in block 360, excess seed layer material is removed. This is illustrated in FIG. 4G, where excess seed layer 470 (e.g., that portion of the seed layer that does not overly one of the bond pads 440) has been removed. Any suitable process (e.g. etching) may be employed to remove the seed layer material.

After the removal of excess seed layer material, what remains is a tubular-shaped bond pad 450 (and a portion of seed layer 470) disposed on I/O bond pad 440s and a solid bump 460 (and a portion of seed layer 470) disposed on power or ground bond pad 440p. The tubular-shaped bump 450 may be similar to the tubular-shaped bump 150 illustrated in FIGS. 1A through 2 and described in the accompanying text above.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

What is claimed is:

1. A device comprising:
an integrated circuit (IC) die including at least a first bond pad disposed on one side thereof; and
a tubular-shaped bump disposed on the first bond pad, the tubular-shaped bump formed from a conductive material.

2. The device of claim 1, wherein the first bond pad is for transmitting input/output (I/O) signals to and from the IC die.

3. The device of claim 2, further comprising a second bond pad disposed on the one side of the IC die and a conductive bump disposed on the second bond pad, the second bond pad for delivering power to the IC die.

4. The device of claim 3, wherein the conductive bump on the second bond pad comprises a tubular-shaped bump.

5. The device of claim 1, wherein the tubular-shaped bump is non-circular.

6. The device of claim 1, wherein the first bond pad and tubular-shaped bump are located proximate a corner of the IC die.

7. The device of claim 1, wherein the tubular-shaped bump includes at least one gap extending through a wall thereof.

8. The device of claim 1, wherein the conductive material comprises copper.

9. A method comprising:
depositing a seed layer over a surface of a substrate, the substrate including at least a first bond pad;
depositing a layer of photoresist (PR) over the seed layer;
patterning the PR layer to define an annular opening over the first bond pad; and
depositing a layer of metal over the seed layer exposed within the annular opening to form a tubular-shaped bump.

10. The method of claim 9, further comprising:
removing the PR layer; and
removing excess seed layer material.

11. The method of claim 9, wherein the first bond pad is for transmitting input/output (I/O) signals.

12. The method of claim 11, wherein the substrate includes a second bond pad, the second bond pad for power delivery, the method further comprising:
defining an opening in the PR layer over the second bond pad; and
depositing the metal layer on the seed layer exposed within the second bond pad opening to form a metal bump on the second bond pad.

13. The method of claim 12, wherein the second bond pad opening comprises an annular opening and the metal bump over the second bond pad comprises a tubular-shaped bump.

14. The method of claim 9, wherein the annular opening is non-circular and the tubular-shaped bump is non-circular.

15. The method of claim 9, wherein the substrate comprises a semiconductor wafer and circuitry for a number of integrated circuit (IC) die has been formed on the wafer.

16. The method of claim 15, wherein the first bond pad and tubular-shaped bump are located proximate a corner of one of the number of die.

17. The method of claim 9, wherein the tubular-shaped bump includes at least one gap extending through a wall thereof.

18. The method of claim 9, wherein the metal comprises copper.
